(19) United States
(12) Patent Application Publication
(10) Pub. No.: US 2015/0110973 A1
(43) Pub. Date: Apr. 23, 2015

(54) PLASMA PROCESSING APPARATUS AND PLASMA PROCESSING METHOD

(71) Applicant: TOKYO ELECTRON LIMITED, Tokyo (JP)

(72) Inventors: Takenao NEMOTO, Miyagi (JP); Toshihisa NOZAWA, Miyagi (JP)

(73) Assignee: TOKYO ELECTRON LIMITED, Tokyo (JP)

(21) Appl. No.: 14/518,101

(22) Filed: Oct. 20, 2014

(30) Foreign Application Priority Data
Oct. 22, 2013 (JP) 2013-218985

(51) Int. Cl. C23C 16/455; C23C 16/50; C23C 16/34

(52) U.S. Cl. CPC C23C 16/45561; C23C 16/345; C23C 16/50; C23C 16/45502
USPC 427/569; 118/723 R

(57) ABSTRACT

A plasma processing apparatus of the present disclosure includes a processing container configured to accommodate a wafer; a placing unit provided on a bottom surface of the processing container to place the wafer thereon; a first processing gas supply pipe provided in a central portion of a ceiling of the processing container to supply a first processing gas into the processing container; a second processing gas supply pipe provided in a side wall of the processing container to supply a second processing gas into the processing container; a rectifying gas supply pipe provided in the side wall of the processing container above the second processing gas supply pipe to supply a rectifying gas downward into the processing container; and a radial line slot antenna configured to radiate microwave into the processing container.

### CROSS-REFERENCE TO RELATED APPLICATIONS

This application is based on and claims priority from Japanese Patent Application No. 2013-218985, filed on Oct. 22, 2013 with the Japan Patent Office, the disclosure of which is incorporated herein in its entirety by reference.

### TECHNICAL FIELD

The present disclosure relates to a plasma processing apparatus in which plasma is generated using a processing gas to process an object to be processed (“workpiece”), and a plasma processing method using the plasma processing apparatus.

### BACKGROUND

Conventionally, a plasma processing apparatus has been known in which a predetermined plasma processing is performed on a workpiece such as, for example, a semiconductor wafer and plasma is generated by introducing microwaves into a processing container. In such a plasma processing apparatus using microwaves, high density plasma having a low electron temperature may be generated under a low pressure in the processing container, and, for example, a film forming processing or an etching processing is performed by the generated plasma.

As the plasma processing apparatus, for example, a plasma processing apparatus disclosed in Japanese Patent Laid-Open Publication No. 2010-118549 has been proposed. As illustrated in FIG. 6, the plasma apparatus 100 includes a processing container 110, a placing table 111, an exhaust unit 112, a microwave supplying unit 113, a first processing gas supply section 114, and a second processing gas supply section 115. The placing unit 111 is provided on a bottom surface of the processing container 110 and a wafer W is placed on the placing unit 111. The exhaust unit 112 is provided in the bottom surface of the processing container 110 outside the placing table to exhaust an atmosphere in the processing container 110. The microwave supplying unit 113 is provided in a ceiling opening of the processing container 110 to supply microwaves into the processing container 110. The first processing gas supply section 114 is provided in a central portion of the ceiling of the processing container 110 (a central portion of the microwave supplying unit 113) to supply a processing gas into the processing container 110. The second processing gas supply section 115 is provided in a side wall of the processing container 110 to supply a processing gas into the processing container 110. In the plasma processing apparatus having the above-mentioned configuration, the processing gases, which are supplied from the first processing gas supply section 114 and the second processing gas supply section 115, respectively, are converted into plasma by the microwaves supplied from the microwaves supplying unit 113. Then, a plasma processing is performed on the wafer W placed on the placing table 111 using the processing gases converted into plasma.

### SUMMARY

The present disclosure provides a plasma processing apparatus comprising: a processing container configured to accommodate an object to be processed (“workpiece”); a placing unit provided on a bottom surface of the processing container to place the workpiece thereon; a first processing gas supply section provided in a central portion of a ceiling of the processing container to supply a processing gas into the processing container; a second processing gas supply section provided in a side wall of the processing container to supply a processing gas into the processing container; a rectifying gas supply section provided outside the first processing gas supply section and above the second processing gas supply section to supply a rectifying gas downward into the processing container; and a plasma generating unit configured to generate plasma using the processing gases which are supplied from the first processing gas supply section and the second processing gas supply section, respectively.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a vertical cross-sectional view schematically illustrating a plasma processing apparatus according to an exemplary embodiment of the present disclosure.

FIG. 2 is an explanatory view illustrating flows of a processing gas and a rectifying gas in the plasma processing apparatus.

FIG. 3 is a horizontal cross-sectional view illustrating arrangement of rectifying gas supply pipes.

FIG. 4 is an explanatory view illustrating a film thickness distribution of a SiN film formed on a wafer in a case of changing a flow rate of a second processing gas and a flow rate of a rectifying gas.

FIG. 5 is a vertical cross-sectional view schematically illustrating a plasma processing apparatus according to another exemplary embodiment.

FIG. 6 is an explanatory view illustrating flow of a processing gas and a rectifying gas in a conventional plasma processing apparatus.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

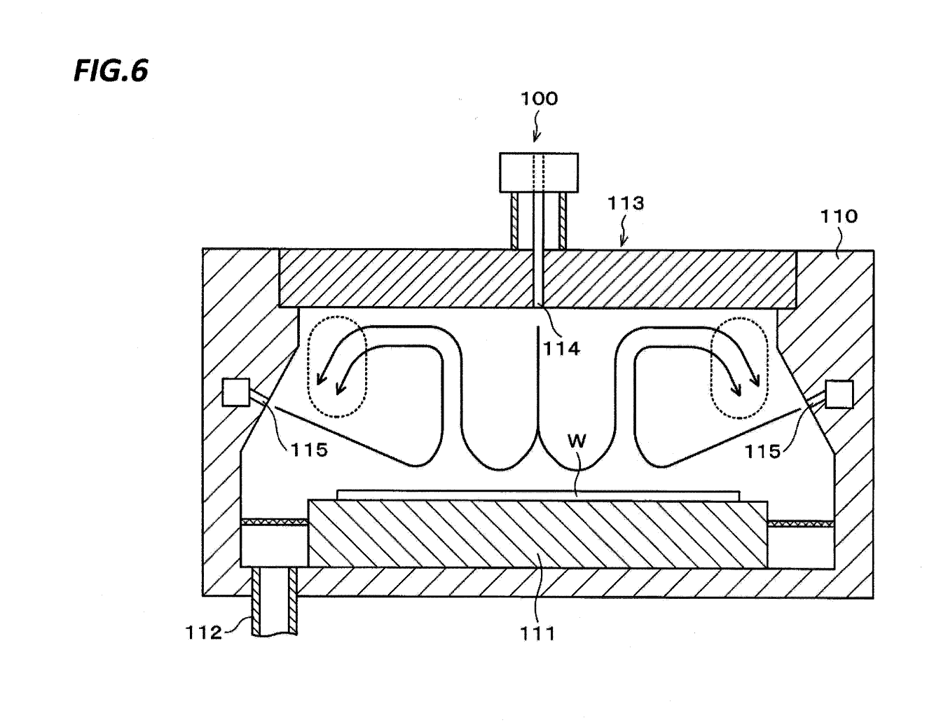

In a case where the plasma processing apparatus 100 as described in Japanese Patent Laid-Open Publication No. 2010-118549 is used, as illustrated in FIG. 6, the processing gas supplied from the first processing gas supply section 114 and the processing gas supplied from the second processing gas supply section 115 collide with each other on the wafer W placed on the placing table 111, and further flow upward in the processing container 10. That is, after the plasma processing has been finished, the processing gases flow upward in the processing container 110 without being exhausted from the exhaust unit 112.

When the flow of the processing gases in the processing container 110 is disturbed in this way, for example, the processing gases are supplied to the wafer W non-uniformly in plane, or the processing gases remain in the processing container 110 more than needs so that the processing gases are dissociated excessively. Accordingly, the plasma processing may not be performed on the wafer W with in-plane uniformity.

Further, the gases remaining, for example, in an upper peripheral portion (regions indicated by dotted lines in FIG. 6) in the processing container 110 may cause generation of particles.

The present disclosure has been made in consideration of the above-mentioned problems, and is to rectify a processing gas in a plasma processing apparatus so that a plasma processing may be performed appropriately.

According to an aspect of the present disclosure, a plasma processing apparatus includes: a processing container configured to accommodate a workpiece; a placing unit provided on a bottom surface of the processing container to place the workpiece thereon; a first processing gas supply section provided in a central portion of a ceiling of the processing container to supply processing gas into the processing container; a second processing gas supply section provided in a side wall of the processing container to supply processing gas into the processing container; a rectifying gas supply section provided outside the first processing gas supply section and above the second processing gas supply section to supply rectifying gas downward into the processing container; and a plasma generating unit configured to generate plasma using the processing gases which are supplied from the first processing gas supply section and the second processing gas supply section, respectively.

In the plasma processing apparatus of the present disclosure, a processing gas is supplied from the first processing gas supply section, and a processing gas is supplied from the second processing gas supply section, and furthermore, a rectifying gas flowing downward into the processing container is supplied from the rectifying gas supply section. Since the rectifying gas flows downward into the processing container in this manner, the processing gases may be suppressed from rising from the placing unit in the processing container as in the prior art. Therefore, the processing gases in the processing container may be rectified. Accordingly, since the processing gases are supplied appropriately onto the workpiece placed on the placing unit, the plasma processing may be performed on the workpiece with in-plane uniformity. Further, since no gas remains in the processing container, generation of particles may be suppressed. According to the present disclosure, the plasma processing may be performed appropriately.

The rectifying gas supply section may be provided in the side wall of the processing container to supply the rectifying gas into the processing container.

A flow rate of the rectifying gas supplied from the rectifying gas supply section may be higher than that of the processing gas supplied from the second processing gas supply section.

The second processing gas supply section may supply the processing gas toward the workpiece placed on the placing unit.

A distance between the ceiling of the processing container and a top surface of the placing unit may be 100 mm to 200 mm.

According to another aspect of the present disclosure, a plasma processing method includes: supplying processing gas into the processing container from a first processing gas supply section provided in a central portion of a ceiling of the processing container; supplying processing gas into the processing container from a second processing gas supply section provided in a side wall of the processing container; supplying a rectifying gas downward into the processing container from a rectifying gas supply section provided outside the first processing gas supply section and above the second processing gas supply section; and generating plasma using the processing gases from the processing gases, which are supplied from the first processing gas supply section and the second processing gas supply section, respectively, to process a workpiece placed on a placing unit in the processing container.

The rectifying gas supply section may be provided in the side wall of the processing container to supply the rectifying gas into the processing container.

A flow rate of the rectifying gas supplied from the rectifying gas supply section may be higher than that of the processing gas supplied from the second processing gas supply section.

The second processing gas supply section may supply the processing gas toward the workpiece placed on the placing unit.

According to the present disclosure, a processing gas in the plasma processing apparatus may be rectified so that a plasma processing may be performed appropriately.

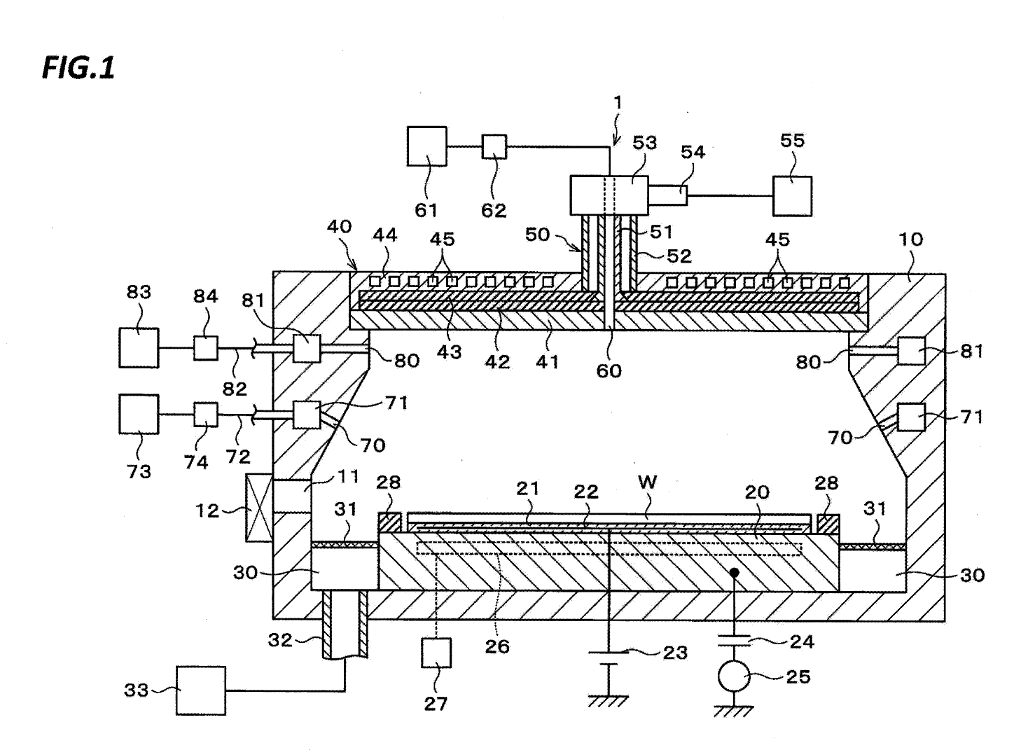

Hereinafter, exemplary embodiments of the present disclosure will be described. FIG. 1 is a vertical cross-sectional view schematically illustrating a plasma processing apparatus 1 according to an exemplary embodiment. In the plasma processing apparatus 1 of the present exemplary embodiment, a plasma chemical vapor deposition (CVD) processing is performed on a surface of a wafer W serving as a workpiece to form a SiN film (silicon nitride film) on the surface of the wafer W.

The plasma processing apparatus 1 is provided with a processing apparatus 10 as illustrated in FIG. 1. The processing container 10 has a substantially cylindrical shape with an opened ceiling, and a radial line slot antenna 40 to be described later is disposed in the ceiling opening. Further, a carry-in/out port 11 of a wafer W is formed in a side wall of the processing container 10, and a gate valve 12 is provided in the carry-in/out port 11. In addition, the processing container 10 is configured such that the inside thereof is sealable. Further, the processing container 10 is made of metal such as aluminum or stainless steel. The processing container 10 is grounded.

A placing table 20 is provided on a bottom surface of the processing container 10 as a placing unit to place a wafer W thereon. The placing table 20 has a cylindrical shape. Further, the placing table 20 is made of, for example, aluminum.

An electrostatic chuck 21 is provided on a top surface of the placing table 20. The electrostatic chuck 21 has a configuration in which an electrode 22 is interposed between insulating materials. The electrode 22 is connected to a direct current (DC) power supply 23 provided outside the processing container 10. The wafer W may be electrostatically attracted on the placing table by a Coulomb force generated on the surface of the placing table 20 by the DC power supply 23.

Further, the placing table 20 may be connected with a high-frequency power supply 25 for RF bias via a condenser 24. The high-frequency power supply 25 outputs a predetermined power having a certain frequency suitable to control energy of ions drawn to the wafer W, for example, a high-frequency of 13.56 MHz.

Further, a temperature adjusting mechanism 26 is provided inside the placing table 20 in which, for example, a cooling medium flows through the temperature adjusting mechanism 26. The temperature adjusting mechanism 26 is connected to a liquid temperature adjusting unit 27 configured to control a temperature of the cooling medium. The temperature of the cooling medium may be controlled by the liquid temperature adjusting unit 27 to control the temperature of the placing table 20. As a result, the wafer W placed on the placing table 20 may be maintained at a predetermined temperature. Further, the placing table 20 is formed with a gas passage (not illustrated) configured to supply a heat transfer medium such as, for example, helium (He) gas onto a rear surface of the wafer W at a predetermined pressure (back pressure).

An annular focus ring 28 is provided on the top surface of the placing table 20 to surround the wafer W on the electrostatic chuck 21. The focus ring 28 is made of an insulating material such as, for example, ceramics or quartz. The focus ring 28 functions to enhance the uniformity of the plasma processing.

Elevation pins (not illustrated) are provided below the placing table 20 to support the wafer W from the bottom and move up and down the wafer W. The elevation pins are configured to pass through through-holes (not illustrated) formed in the placing table 20 and protrude from the top surface of the placing table 20.

Around the placing table 20, an annular exhaust space 30 is formed between the placing table 20 and the side wall of the processing container 10. An annular baffle plate 31 formed with a plurality of exhaust holes is provided in the upper portion of the exhaust space 30 to uniformly exhaust an atmosphere in the processing container 10. An exhaust pipe 32 is connected to the bottom surface of the processing container 10 serving as a bottom of the exhaust space 30. The number of exhaust pipes 32 may be optionally set, and a plurality of exhaust pipes 32 may be formed circumferentially. The exhaust pipes 32 are connected to an exhaust device 33 provided with, for example, a vacuum pump. The exhaust device 33 may decompress the atmosphere in the processing container 10 to a predetermined degree of vacuum.

A radial line slot antenna 40 is provided in the ceiling opening of the processing container 10 to supply microwaves for producing plasma. The radial line slot antenna 40 is provided with a microwave transmission plate 41, a slot plate 42, a slow-wave plate 43, and a shield lid 44.

The microwave transmission plate 41 is closely fitted in the ceiling opening of the processing container 10 through a seal member (not illustrated) such as, for example, an O-ring. Accordingly, the inside of the processing container 10 is maintained hermetically. The microwave transmission plate 41 is made of, for example, quartz, Al₂O₃ or AlN. The microwave transmission plate 41 transmits microwaves.

The slot plate 42 is disposed on the top surface of the microwave transmission plate 41 and provided to be opposite to the placing table 20. The slot plate 42 is formed with a plurality of slots. The slot plate 42 functions as an antenna. The slot plate 42 is made of a conductive material such as, for example, copper, aluminum or nickel.

The slow-wave plate 43 is provided on the top surface of the slot plate 42. The slow-wave plate 43 is made of a low-loss dielectric material such as, for example, quartz, Al₂O₃ or MN. The slow-wave plate 43 shortens the wavelength of the microwaves.

The shield lid 44 is provided on the top surface of the slow-wave plate 43 to cover the slow-wave plate 43 and the slot plate 42. A plurality of annular flow paths 45 is provided inside the shield lid 44 to circulate, for example, a cooling medium. The microwave transmission plate 41, the slot plate 42, the slow-wave plate 43, and the shield lid 44 are controlled to a predetermined temperature by the cooling medium circulating through the flow paths 45.

A coaxial waveguide 50 is connected to a central portion of the shield lid 44. The coaxial waveguide 50 is provided with an internal conductor 51 and an external tube 52. The internal conductor 51 is connected to the slot plate 42. The slot plate 42 side of the internal conductor 51 is formed conically to efficiently propagate the microwaves to the slot plate 42.

The coaxial waveguide 50 is connected with a mode converter 53 that converts the microwaves into a predetermined vibration mode, a rectangular waveguide 54, and a microwave generator 55 in this order from the coaxial waveguide 50. The microwave generator 55 generates microwaves of a predetermined frequency, for example, 2.45 GHz.

With such a configuration, the microwaves generated by the microwave generator 55 are propagated sequentially through the rectangular waveguide 54, the mode converter 53 and the coaxial waveguide 50 to be supplied into the radial line slot antenna 40, and compressed by the slow-wave plate 43 to be shortened in wavelength. After generating circularly polarized waves in the slot plate 42, the microwaves are transmitted through the microwave transmission plate 41 from the slot plate 42, and then, radiated into the processing container 10. The processing gas is converted into plasma in the processing container by the microwaves, and a plasma processing of the wafer W is performed by the plasma.

Further, in the present exemplary embodiment, the radial line slot antenna 40, the coaxial waveguide 50, the mode converter 53, the rectangular waveguide 54, and the microwave generator 55 constitute a plasma generating unit in the present disclosure.

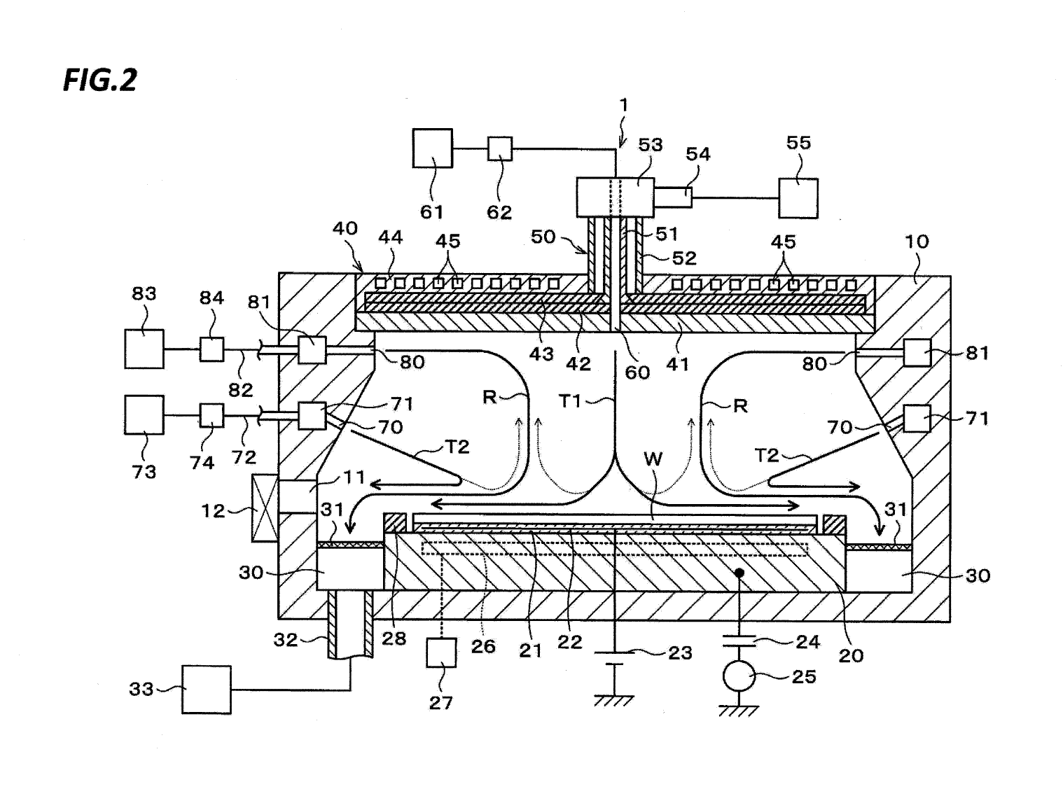

A first processing gas supply pipe 60 serving as the first processing gas supply section is provided in the central portion of the ceiling of the processing container 10, that is, the radial line slot antenna 40. The first processing gas supply pipe 60 penetrates the radial line slot antenna 40, and one end of the first processing gas supply pipe 60 is opened on the bottom surface of the microwave transmission plate 41. Further, the first processing gas supply pipe 60 penetrates the inside of the internal conductor 51 of the coaxial waveguide 50 and is inserted through the inside of the mode converter 53 so that the other end of the first processing gas supply pipe 60 is connected to a first processing gas source 61. Processing gases such as, for example, trisilylamine (TSA), N₂ gas, H₂ gas and Ar gas are stored separately in the first processing gas source 61. Among them, TSA, N₂ gas and H₂ gas are material gases for film formation, and Ar gas is a gas for plasma excitation. Hereinafter, these processing gases may be collectively referred to as a “first processing gas”. Further, a supply equipment group 62 including a valve or flow rate regulating unit for controlling the flow of the first processing gas is provided in the first processing gas supply pipe 60. In addition, as illustrated in FIG. 2, the first processing gas T1 supplied from the first processing gas source 61 is supplied into the processing container 10 through the first processing gas supply pipe 60. The first processing gas T1 flows vertically downwardly towards the wafer W placed on the placing table 20 in the processing container 10.

As illustrated in FIG. 1, a second processing gas supply pipe 70 serving as a second processing gas supply section is provided in the side wall of the processing container 10. A plurality of (e.g., twenty four) second processing gas supply pipes 70 is provided at equal intervals on the circumference in the side wall of the processing container 10. One end of each second processing gas supply pipe 70 is opened in the side wall of the processing container 10, and the other end is connected to a buffer section 71. Each second processing gas supply pipe 70 is disposed obliquely such that the one end is positioned below the other end.

The buffer section 71 is provided annularly inside the side wall of the processing container 10 and commonly to the plurality of second processing gas supply pipes 70. The buffer section 71 is connected with a second processing gas source 73 through the supply pipes 72. Processing gases such as, for example, trisilylamine (TSA), N₂ gas, H₂ gas and Ar gas are stored separately in the second processing gas source 73. Hereinafter, these processing gases may be collectively referred to as a “second processing gas”. Further, a supply equipment group 74 including, for example, a valve or a flow rate regulating unit for controlling the flow of the second processing gas is provided in the second processing gas supply pipes 72. In addition, as illustrated in FIG. 2, a second processing gas T2 supplied from the second processing gas source 73 is introduced into the buffer section 71 through the supply pipes 72, and supplied into the processing container 10 through the second processing gas supply pipes 70 after equalizing the pressure in the circumferential direction in the buffer section 71. The second processing gas T2 flows obliquely downwardly towards the outer peripheral portion of the wafer W placed on the placing table 20 in the processing container 10.

As described above, the first processing gas T1 from the first processing gas supply pipe 60 is supplied towards the central portion of the wafer W, and the second processing gas T2 from the second processing gas supply pipes 70 is supplied towards the outer peripheral portion of the wafer W.

Further, the processing gases T1, T2, which are supplied into the processing container 10 from the first processing gas supply pipe 60 and the second processing gas supply pipes 70, respectively, may be the same as or different from each other, and each may be supplied at an independent flow rate, or at any flow ratio.

As illustrated in FIG. 1, a rectifying gas supply pipe 80 serving as a rectifying gas supply section is provided in the side wall of the processing container 10 and above a second processing supply pipe 70. The rectifying gas supply pipe 80 is provided such that the axial direction thereof extends horizontally.

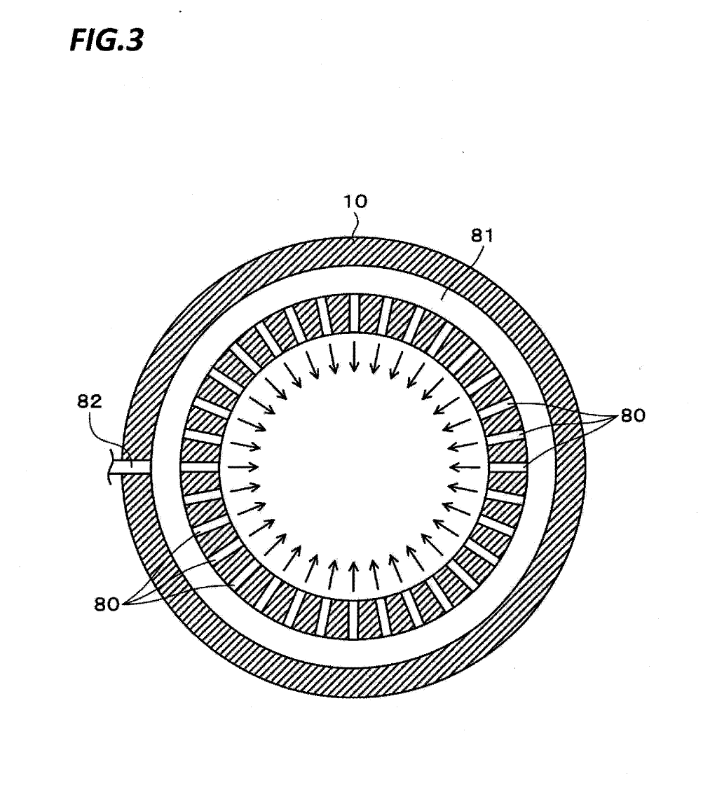

As illustrated in FIG. 3, a plurality of (e.g., thirty two) rectifying gas supply pipes 80 is provided at equal intervals on the circumference in the side wall of the processing container 10. One end of each rectifying gas supply pipe 80 is opened in the side wall of the processing container 10, and the other end is connected to the buffer section 81. The buffer section 81 is provided annularly in the inside of the side wall of the processing container 10 and commonly to the plurality of rectifying gas supply pipes 80.

As illustrated in FIG. 1, the buffer section 81 is connected with a rectifying gas source 83 through a second processing gas supply pipe 82. A rectifying gas such as, for example, Ar gas, which is an inert gas, is stored in the rectifying gas source 83. Further, a supply equipment group 84 including a valve or flow rate regulating unit for controlling the flow of the rectifying gas is provided in the second processing gas supply pipe 82. The flow rate of the rectifying gas (Ar gas) supplied from the rectifying gas supply pipes 80 is higher than at least the flow rate of Ar gas supplied from the second processing gas supply pipes 70, and more preferably higher than the total flow rate of Ar gas supplied from the first processing gas supply pipe 60 and the second gas supply pipes 70. The flow rate of Ar gas is dominant in the processing gases.

In addition, as illustrated in FIG. 2, the rectifying gas R supplied from the rectifying gas source 83 is introduced into the buffer section 81 through the supply pipe 82, and supplied into the processing container 10 through the rectifying gas supply pipes 80 after equalizing the pressure in the circumferential direction in the buffer section 81. The rectifying gas R from the rectifying gas supply pipes 80 flows horizontally in the processing container 10.

Next, descriptions will be made on the plasma processing of the wafer W performed in the plasma processing apparatus 1 having the above-mentioned configuration. In the present exemplary embodiment, a plasma film forming processing is performed on a wafer W as described above to form a SiN film on the surface of the wafer W.

First, the gate valve 12 is opened, and a wafer W is carried into the processing container 10. The wafer W is placed on the placing table 20 by the elevation pins. At this time, the DC power supply 23 is turned ON to apply a DC voltage to the electrode 22 of the electrostatic chuck 21 such that the wafer W is electrostatically attracted on the electrostatic chuck 21 by a Coulomb force of the electrostatic chuck 21. Then, after the gate valve 12 is closed and the processing container 10 is sealed, the exhaust device 33 is operated to decompress the atmosphere in the processing container 10 to a predetermined pressure, for example, 400 mTorr (53 Pa).

Then, the first processing gas T1 is supplied from the first processing gas supply pipe 60 into the processing container 10, the second processing gas T2 is supplied from the second processing gas supply pipes 70 into the processing container 10, and the rectifying gas R is supplied from the rectifying gas supply pipes 80 into the processing container 10. At this time, the flow rate of Ar gas supplied from the first processing gas supply pipe 60 is, for example, 100 sccm (ml/min), the flow rate of Ar gas supplied from the second processing gas supply pipes 70 is, for example, 750 sccm (ml/min), and the flow rate of Ar gas supplied from the rectifying gas supply pipes 80 is, for example, 1,000 sccm (ml/min). That is, the flow rate of the Ar gas supplied from the rectifying gas supply pipes 80 is higher than the total flow rate of the Ar gas supplied from the first processing gas supply pipe 60 and the second processing gas supply pipes 70.

As illustrated in FIG. 2, the rectifying gas R supplied from the rectifying gas supply pipes 80 into the processing container 10 flows horizontally, and then, vertically downwardly. The rectifying gas R flows vertically downwardly in this way because the rectifying gas R follows the vertically downward flow of the first processing gas T1 from the first processing gas supply pipe 60. The rectifying gas R that flows vertically downwardly reaches a region above the wafer W placed on the placing table 20, and then, flows towards the exhaust space 30 radially outward of the wafer W by the exhaust device 33.

The first processing gas T1 supplied from the first processing gas supply pipe 60 into the processing container 10 flows downwardly towards the central portion of the wafer W placed on the placing table 20. In a conventional case, after reaching the region above the central portion of the wafer W placed on the placing table 20, the first processing gas T1 collides with the wafer W and flows upwardly in the processing container 10 (as indicated by dotted lines in the figure). On the contrary, in the present exemplary embodiment, the upward flow of the first processing gas T1 is suppressed by the downward flow of the rectifying gas R as described above. Then, the first processing gas T1 flows towards the exhaust space 30 radially outward of the wafer W by the rectifying gas R.

The second processing gas T2 supplied from the second processing gas supply pipes 70 into the processing container 10 flows obliquely downwardly towards the outer peripheral portion of the wafer W placed on the placing table 20. In a conventional case, after reaching a region above the outer peripheral portion of the wafer W placed on the placing table 20, the second processing gas T2 collides with the wafer W and flows upwardly in the processing container 10 (as indicated by dotted lines in the figure). On the contrary, in the present exemplary embodiment, the upward flow of the second processing gas T2 is suppressed by the downward flow of the rectifying gas R as described above. Then, the second processing gas T2 flows towards the exhaust space 30 radially outward of the wafer W by the rectifying gas R.

As described above, the first processing gas T1 and the second processing gas T2 are rectified appropriately by the rectifying gas R, supplied to the wafer W on the placing table 20, and then, exhausted from the exhaust pipe 32 without rising in the processing container 10. Therefore, no gas remains in the processing container, and hence, generation of particles is suppressed.

When the first processing gas T1, the second processing gas T2, and the rectifying gas R are supplied into the processing container, the microwave generator 55 is operated to generate microwaves of a predetermined power at a frequency of, for example, 2.45 GHz. The microwaves are radiated into the processing container 10 through the rectangular waveguide 54, the mode converter 53, the coaxial waveguide 50, and the radial line slot antenna 40. In the processing container 10, the processing gases T1, T2 are converted into plasma by the microwaves, and dissociation of the processing gases T1, T2 proceed in the plasma. Consequently, a film forming processing is performed on the wafer W by the active species generated at that time. At this time, since the processing gases T1, T2 are rectified by the rectifying gas R and flow equally on the wafer W radially outwardly, the plasma processing by the processing gases T1, T2 may be performed on the wafer W with in-plane uniformity. Therefore, a SiN film is formed on the surface of the wafer W.

While the plasma film forming processing is performed on the wafer W, the high-frequency power supply 25 may be turned ON to output high-frequency waves of a predetermined power at a frequency of, for example, 13.56 MHz. The high-frequency waves are applied to the placing table 20 through the condenser 24, and an RF bias is applied to the wafer W. In the plasma processing apparatus 1, since a low electron temperature of the plasma can be maintained, no damage is caused to the film. Furthermore, since molecules of the processing gases are likely to be dissociated by the high density plasma, the reaction is promoted. In addition, the application of the RF bias within an appropriate range acts to draw ions in the plasma into the wafer W. Therefore, denseness of the SiN film may be enhanced, and trap in the film may be increased.

Thereafter, when the SiN film grows and hence the SiN film having a predetermined film thickness is formed on the wafer W, the supply of the first processing gas T1, the second processing gas T2 and the rectifying gas R, and the irradiation of the microwaves are stopped. Then, the wafer W is carried out from the processing container 10, and a series of the plasma film forming processings are terminated.

According to the above-mentioned exemplary embodiment, the first processing gas T1 is supplied from the first processing gas supply pipe 60, the second processing gas T2 is supplied from the second processing gas supply pipes 70, and the rectifying gas R is further supplied from the rectifying gas supply pipes 80. Since the rectifying gas R flows horizontally, and then, flows vertically downwardly in the processing container 10, the processing gases may be suppressed from rising from the placing table 20 in the processing container 10 as in the prior art. Accordingly, the processing gases T1, T2 in the processing container 10 may be rectified. By doing this, the processing gases T1, T2 may be supplied appropriately onto the wafer W placed on the placing table 20. Therefore, the plasma processing may be performed on the wafer W with in-plane uniformity. Further, since no gas remains in the processing container 10, generation of particles may be suppressed. Accordingly, in the plasma processing apparatus 1 of the present exemplary embodiment, the plasma processing may be performed appropriately.

In the plasma processing apparatus 1 of the present exemplary embodiment, a distance between the bottom surface of the microwave transmission plate 41 (the ceiling of the processing container 10) and the top surface of the electrostatic chuck 21 (the top of the placing table 20) is 100 mm to 200 mm. That is, the plasma processing space in the processing container 10 is large. When the plasma processing space is large like this, the flow of the processing gases becomes complicated, and, for example, an upward flow of the processing gases is easy to occur as in the prior art. Thus, the present disclosure in which the processing gases T1, T2 are rectified by the rectifying gas R is particularly useful for a plasma processing apparatus having a large plasma processing space, for example, the plasma processing apparatus 1 using the radial line slot antenna 40 as in the present exemplary embodiment.

Further, according to the present exemplary embodiment, the first processing gas T1 from the first processing gas supply pipe 60 is supplied towards the central portion of the wafer W, and the second processing gas T2 from the second processing gas supply pipes 70 is supplied towards the outer peripheral portion of the wafer W. That is, the central portion of the wafer W is subjected to a film forming processing with a fresh first processing gas T1, and the outer peripheral portion of the wafer W is subjected to a film forming processing with a fresh second processing gas T2. Thus, since a fresh processing gas is supplied to all in-plane sites of the wafer W, the in-plane uniformity of the plasma processing on the wafer W may be further enhanced.

Further, the denseness of the SiN film formed on the wafer W may be controlled more accurately by supplying the first processing gas T1 and the second processing gas T2 directly to the central portion and the outer peripheral portion of the wafer W, respectively, as in the present exemplary embodiment, as compared with a case where a processing gas is supplied to a part of the wafer W and the processing gas is diffused on the wafer W.

Further, the film thickness of the SiN film formed on the peripheral portion of the wafer W may be controlled appropriately, and the film thickness of the SiN film on the entire surface of the wafer W may be freely controlled by controlling the flow rate of the second processing gas T2.

Further, according to the present exemplary embodiment, since the flow rate of Ar gas supplied from the rectifying gas supply pipes 80 is larger than the total flow rate of Ar gas supplied from the first processing gas supply pipe 60 and the second processing gas supply pipes 70, an upward flow of the processing gases T1, T2 may be more securely suppressed by the rectifying gas R. Further, the present inventors have studied intensively and found that, when the flow rate of Ar gas supplied from the rectifying gas supply pipes 80 is larger than at least the flow rate of Ar gas supplied from the second processing gas supply pipes 70, rising of the processing gases T1, T2 may be suppressed by the rectifying gas R.

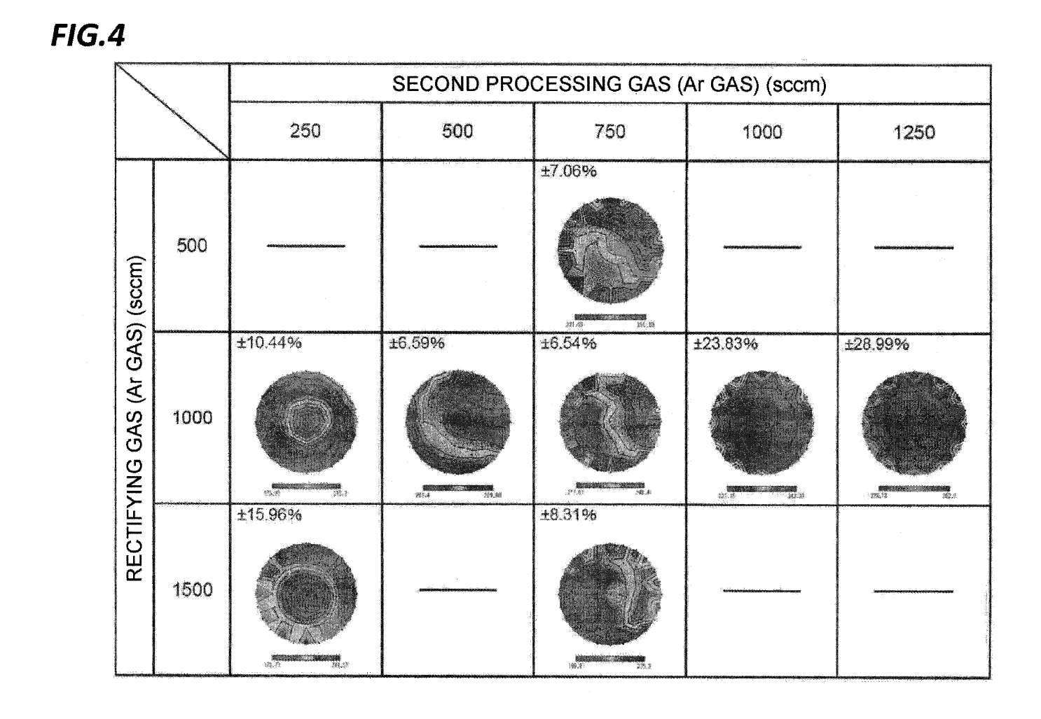

Here, the flow rate of the rectifying gas R supplied from the rectifying gas supply pipes 80 will be described. FIG. 4 illustrates a result of performing the plasma processing in a case where the flow rate of Ar gas of the second processing gas T2 supplied from the second processing gas supply pipes 70 and the flow rate of the rectifying gas R (Ar gas) supplied from the rectifying gas supply pipes 80 are changed. FIG. 4 illustrates an in-plane distribution of the film thickness of the SiN film formed on the surface of the wafer W, and the percentages (%) in FIG. 4 represents a ratio of a difference in film thickness between the maximum film thickness and the minimum film thickness in the plane of the wafer W with respect to a desired film thickness. The flow rate of Ar gas of the second processing gas T2 is changed to 250 sccm, 500 sccm, 750 sccm, 1,000 sccm, and 1,250 sccm. The flow rate of Ar gas of the rectifying gas R is changed to 500 sccm, 1,000 sccm, and 1,500 sccm. Since other plasma processing conditions are common, descriptions thereof will be omitted.

Referring to FIG. 4, the minimum ratio of the difference in film thickness, that is, the highest in-plane uniformity of the SiN film is obtained in a case where the flow rate of the Ar gas of the second processing gas T2 is 750 sccm and the flow rate of the rectifying gas R is 1,000 sccm. Accordingly, the optimal flow rate of the rectifying gas R is 1,000 sccm under the present processing conditions.

Further, as an example of the above-mentioned optimal flow rate of the rectifying gas R, the optimal flow rate of the rectifying gas R is determined depending on the plasma processing conditions.

Exemplary embodiments of the present disclosure have been described with reference to the accompanying drawings, but the present disclosure is not limited thereto. It is evident that various modifications or changes are conceived by those skilled in the art within the scope of the claims appended herewith, and it will be understood that the modifications or the changes belong to the technical scope of the present disclosure.

In the plasma processing apparatus 1 of the above-mentioned exemplary embodiment, the rectifying gas supply pipes 80 are provided in the side wall of the processing container 10, but is not limited thereto as long as the rectifying gas supply pipes 80 are positioned outside the first processing gas supply pipe 60 and above the second processing gas supply pipes 70.

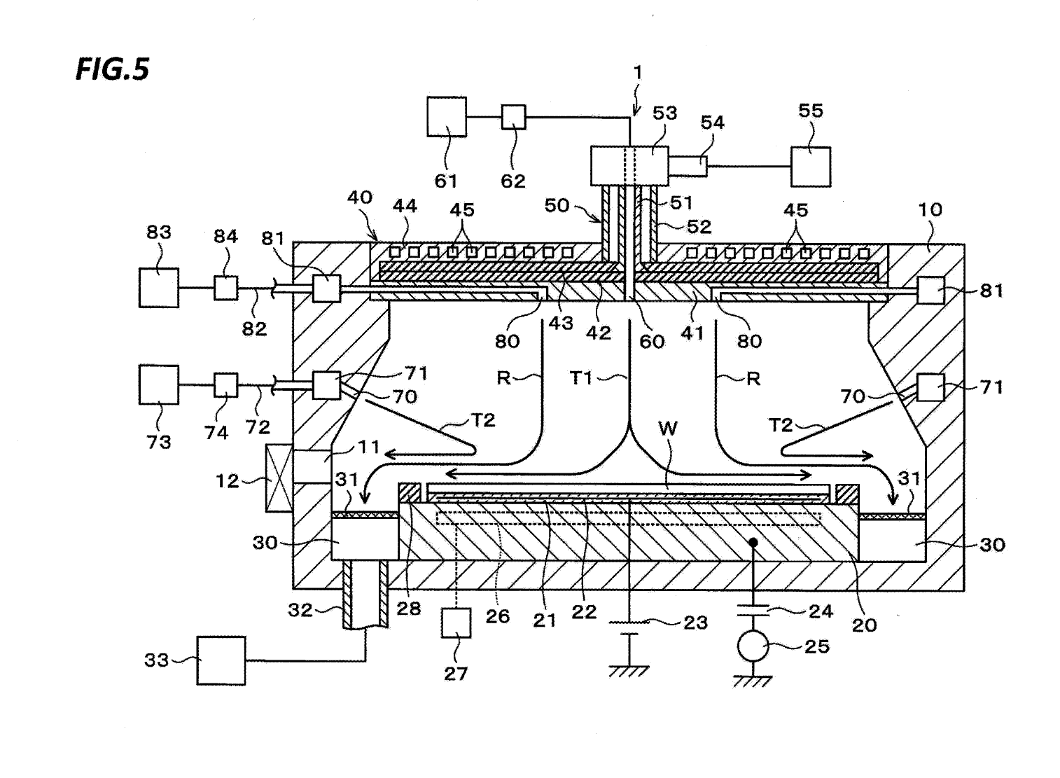

For example, as illustrated in FIG. 5, the rectifying gas supply pipes 80 may be provided on the ceiling of the processing container 10, that is, the bottom surface of the microwave transmission plate 41. One end of each rectifying gas supply pipe 80 is opened to the bottom surface of the microwave transmission plate 41, and the other end is connected to the buffer section 81. Further, a plurality of (e.g., thirty two) rectifying gas supply pipes 80 is provided around the first gas supply pipe 60. Since the configuration of the plurality of rectifying gas supply pipes 80, and the buffer section 81, the supply pipe 82, the rectifying gas source 83 and the supply equipment group 84 associated therewith is the same as in the above-mentioned exemplary embodiment, descriptions thereof will be omitted.

Even in such a case, the same effects as those in the above-mentioned exemplary embodiments may be obtained. That is, since the rectifying gas R from the rectifying gas supply pipes 80 flows vertically downwardly in the processing container 10, the processing gas may be suppressed from rising from the placing table 20 side in the processing container as in the prior art, so that the processing gases T1, T2 in the processing container 10 may be rectified. Accordingly, the plasma processing may be performed appropriately in the plasma processing apparatus 1 of the present exemplary embodiment.

Further, in the above-mentioned exemplary embodiment, the rectifying gas R supplied from the rectifying gas supply pipes 80 was Ar gas, but, in addition to this, the rectifying gas R may include TSA, N₂ gas, and H₂ gas, like the processing gases T1, T2. In this case, the rectifying R contributes to rectification of the processing gases T1, T2, as well as the plasma film forming processing on the wafer W. Accordingly, the in-plane uniformity of the film thickness of the SiN film formed on the wafer W may be further enhanced.

Further, in the above-mentioned exemplary embodiments, the plasma processing using microwaves was exemplified, but the present disclosure is not limited thereto, and is also applicable to a plasma processing using a high-frequency voltage. Further, in the above-mentioned exemplary embodiment, the present disclosure was applied to the plasma processing for film formation, but is also applicable to a plasma processing for etching or sputtering. In addition, the workpiece to be processed by the plasma processing of the present disclosure may be any substrate such as, for example, a glass substrate, an organic EL substrate, and a substrate for flat panel display (FPD).

The present disclosure is useful for a plasma processing of, for example, semiconductor wafers, particularly, a plasma processing using a radial line slot antenna.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a processing container configured to accommodate an object to be processed (“workpiece”);
a placing unit provided on a bottom surface of the processing container to place the workpiece thereon;
a first processing gas supply section provided in a central portion of a ceiling of the processing container to supply a processing gas into the processing container;
a second processing gas supply section provided in a side wall of the processing container to supply a processing gas into the processing container;
a rectifying gas supply section provided outside the first processing gas supply section and above the second processing gas supply section to supply a rectifying gas downward into the processing container; and
a plasma generating unit configured to generate plasma using the processing gases which are supplied from the first processing gas supply section and the second processing gas supply section, respectively.

2. The plasma processing apparatus of claim 1, wherein the rectifying gas supply section is provided in the side wall of the processing container to supply the rectifying gas into the processing container.

3. The plasma processing apparatus of claim 1, wherein a flow rate of the rectifying gas supplied from the rectifying gas supply section is higher than that of the processing gas supplied from the second processing gas supply section.

4. The plasma processing apparatus of claim 1, wherein the second processing gas supply section supplies the processing gas toward the workpiece placed on the placing unit.

5. The plasma processing apparatus of claim 1, wherein a distance between the ceiling of the processing container and a top surface of the placing unit is 100 mm to 200 mm.

6. A plasma processing method comprising:
supplying a processing gas into the processing container from a first processing gas supply section provided in a central portion of a ceiling of the processing container;
supplying a processing gas into the processing container from a second processing gas supply section provided in a side wall of the processing container;
supplying a rectifying gas downward into the processing container from a rectifying gas supply section provided outside the first processing gas supply section and above the second processing gas supply section; and
generating plasma using the processing gases from the processing gases, which are supplied from the first processing gas supply section and the second processing gas supply section, respectively, to process a workpiece placed on a placing unit in the processing container.

7. The plasma processing method of claim 6, wherein the rectifying gas supply section is provided in the side wall of the processing container to supply the rectifying gas into the processing container.

8. The plasma processing method of claim 6, wherein a flow rate of the rectifying gas supplied from the rectifying gas supply section is higher than that of the processing gas supplied from the second processing gas supply section.

9. The plasma processing method of claim 6, wherein the second processing gas supply section supplies the processing gas toward the workpiece placed on the placing unit.
